(19) United States
(12) Patent Application Publication
(10) Pub. No.: US 2008/0315217 A1
(43) Pub. Date: Dec. 25, 2008

(54) Semiconductor Light Source and Method of Producing Light of a Desired Color Point

(75) Inventor: Pieter Joseph Clara Van Der Wel, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/097,083

(22) PCT Filed: Dec. 7, 2006
(86) PCT No.: PCT/IB2006/054652

§ 371 Date: Jun. 12, 2008

(30) Foreign Application Priority Data
Dec. 14, 2005 (EP) 05112091.3

(51) Int. Cl. H01L 33/00

(52) U.S. Cl. 257/88; 257/E33.001

(57) ABSTRACT

This invention relates to a solid-state light source (100) comprising a first active region (110) for emitting an excitation light (102) and a second active region (120) for emitting a primary light (104), and a conversion element (130) for substantially converting the excitation light (102) into a secondary light (104). The primary light (104) and the secondary light (106) are mixed to produce light of a desired color point, in particular white light, with a predetermined color temperature.

The present invention relates to a solid-state light source.

The present invention further relates to a backlight unit comprising such solid-state light sources.

The present invention further relates to a display module comprising such a backlight unit.

The present invention further relates to a portable electronic device, such as a mobile phone, a PDA, a pocket personal computer etc., comprising such a display module.

This invention further relates to a lamp comprising such solid-state light sources.

The present invention further relates to a method of producing light of a desired color point from such a solid-state light source.

An embodiment of a light source, such as an LED lamp, is disclosed in EP-1160883-A2. The LED lamp includes a blue and a red LED. The blue LED produces an emission at a wavelength falling within a blue wavelength range, and the red LED produces an emission at a wavelength falling within a red wavelength range. Phosphor covers at least the blue LED. The phosphor is photoexcited by the emission of the blue LED and converts a part of the emission of the blue LED into an intermediate wavelength, for example yellow or green. A part of the emission in the blue wavelength range passes through the phosphor without being converted. White light is produced by combining the emissions produced by the blue LED, the red LED and the yellow luminescence that is exhibited by the phosphor when photoexcited by the emission of the blue LED.

Typically, in applications where light from a single LED is insufficient, and several LEDs need to be put together to provide illumination. This is for example, the case in a backlight unit, for a mobile phone display that relies on a number of white LEDs to provide illumination to the display. Further, it is preferable that these devices, for example a display, have a uniform color temperature. However, certain types of LEDs and especially white LEDs coated with a phosphor, which exhibit variations in color temperature due to differences in raw material sources, crystal growth, handling, storage conditions for the raw materials, and the other variables that go into the manufacturing process. Therefore, the manufacturing process requires the LEDs to be binned before assembling them for example into a backlight unit. These binning methods, for example, use color coordinates or correlated color temperature (CCT) for sorting the LEDs, but LEDs with the same CCT can still have a different color tint. Manufacturers have used new binning strategies that tend to reduce the variability of LEDs within each bin. Such binning processes significantly increase the cost of manufacturing the LEDs.

Therefore, it is an object of the invention to provide a solid-state light source that can be produced at a lower cost by reducing the need for the above-described binning methods.

It is a further object of the invention to provide a method of producing light of a desired color point from a solid-state light source.

According to a first aspect thereof, the present invention provides a solid-state light source comprising a first active region for emitting excitation light, a second active region for emitting primary light, and a conversion element for substantially converting the excitation light into secondary light, and the solid-state light source is further arranged to provide a mixing of the primary light and the secondary light.

The first active region emits the excitation light, for example any one of the colors of blue, red, green, violet, UV etc. The conversion element substantially converts any excitation light into secondary light, for example into any of the colors of yellow, green, blue-green, magenta etc. Preferably, excitation light emitted from the first active region is completely converted into secondary light by the phosphor. The conversion element, is preferably, a phosphor, such as a YAG or UV efficient silicate phosphor, and is capable of absorbing light in one spectral frequency range and emitting light belonging to a different spectral frequency range. As an alternative a fluorescent dye, in particular a hybrid inorganic or organic system may be used. The use of the word “phosphor” hereinafter does not exclude the possibility of using alternatives. The mixing of the primary light and the secondary light produces mixed light, preferably white light, of a uniform color temperature.

The object of the invention is achieved by substantially converting the excitation light into the secondary light, instead of the already known partial conversion, thereby controlling the white point of the solid-state light source, and removing the need for binning the solid-state light sources.

The phosphor associated with the prior art cannot be accurately controlled during the manufacturing process results in variable amounts of light being converted, because the LEDs having a different correlated color temperature, and therefore need to be binned. For example, if the phosphor is in the form of a layer associated with the first active region, then the thickness of the phosphor layer influences the conversion rate or conversion efficiency of the excitation light into secondary light. Further, the composition of the phosphor material may also influence the conversion rate. Variations in the conversion rate lead to a variation in the color temperature as well.

This problem with the variations of the partial conversion is solved by the present invention by substantially converting any excitation light into secondary light. Since any excitation light is substantially converted to secondary light the need for binning is removed, thereby relaxing the process margins resulting in reducing the cost of producing these solid-state light sources.

The excitation light and the primary light are preferably in the blue wavelength range. The phosphor is arranged to absorb the excitation light, blue light, emitted from the first active region and convert the excitation light into light of another wavelength, preferably in a broad spectrum around and including yellow. The primary light, which is blue, and the secondary light, which is now yellow, are mixed to produce white light. The white light thus produced has a high color temperature, and are favored in devices such as portable electronic devices, for example mobile phones, PDAs, pocket PCs etc.

A further advantage of completely converting the excitation light into secondary light is that variations in the conversion rate of the emission spectrum caused by deviations of the operating conditions from the binning conditions become negligible. For example, the solid-state light sources are typically binned at constant currents of 10 mA or 20 mA such that they have the same CCT. However, when several of these are connected in a series for example in a backlight unit, then each solid-state light source in the series may have a different forward voltage drop. Thus, one or several solid-state light sources may operate at a current different from the current applied during binning, and hence have a different intensity resulting in a shift in the emission spectrum. Thus, the solid-state light sources operate at different CCTs. By substantially converting the excitation light, the effect on the emission spectrum is negligible. The substantial conversion of excitation light into secondary light leads to negligible intensity variations of the solid-state light source not anymore disturbing the uniform illumination.

A further advantage of the substantial conversion is that any shift in the emission spectrum caused by the aging of the solid-state light source becomes negligible.

A further advantage of the substantial conversion is that any shift in the emission spectrum caused by a variation in the ambient temperature of the solid-state light source becomes negligible.

A further advantage of the substantial conversion is that any shift in the emission spectrum caused by the variation in material used in the solid-state light source during the production process also becomes negligible.

A further advantage is that any shift in the absorption spectrum of the phosphor, for example due to the aging or chemical compositions, that otherwise has an influence on the conversion typically leading to a decrease in the luminescence of the phosphor also becomes negligible.

For example, for solid-state light sources, effects such as the aging or the variations in the ambient temperature or variation in the materials used, lead to a shift in the emission spectrum and hence result in a variation in the conversion rate, resulting in the solid-state light sources operating at different CCTs. Thus, solid-state light sources, arranged for example in a backlight unit, exhibit distortions on the display because the light converted has different color tints. By converting the excitation light, the effect on the conversion rate and hence the intensity variations becomes negligible resulting in more uniform illumination.

As discussed previously, the variations in the conversion influence the color temperature, which is avoided by the substantially converting the excitation light into secondary light in accordance with the invention. The above consideration on color temperature applies as well to the more general task of achieving light of any desired color point.

In a preferred embodiment, the excitation light and the primary light are in the same wavelength range.

Preferably, the excitation light and the primary light are in the same portion of the visible spectrum, for example blue wavelength range because blue light suffers from less absorption as compared to other light such as red. In most backlight units, polymer lightguide are used, which absorbs light. An advantage of using blue light for generating white light by mixing is because blue light suffers from less absorption and hence improves the efficiency of the system as compared to light of other wavelengths. Further, white light formed by mixing blue light and yellow light also has a high color temperature, because of the presence of blue light, and makes it favourable for used in devices such as mobile phones, etc.

In a further embodiment the first active region and the second active region are formed on a single substrate. An advantage is that the solid-state light source may be integrated in a single chip thereby reducing manufacturing costs. A further advantage is that the number of electrical connections is reduced because a common electrode is attached to the single substrate further reducing the manufacturing costs.

In a further embodiment the first active region and the second active region are arranged within a single common active region formed on a single substrate. A first portion of the single common active region functions as the first active region. For example, the phosphor is associated with the first portion only, such that any excitation light emitted from the first portion is completely converted into secondary light. A second portion of the single common active region is not associated with the phosphor and functions as the second active region for emitting primary light. The excitation light and the primary light have the same wavelength. An advantage is that the cost of production can be significantly reduced because of the use of a single material to form the active regions, thereby reducing manufacturing costs. Further, because of the single substrate, a single common electrode can be attached to the substrate forming the cathode that also reduces the manufacturing cost.

In a further embodiment the first active region is formed on a first substrate and the second active region is formed on a second substrate. An advantage with this construction is that the first active region and second active regions is the flexibility in designing the solid-state light source.

In a further embodiment the conversion element comprises a layer essentially covering the first active region only. For example, the phosphor can be formed as a layer covering only the first active region and substantially converting any excitation light into secondary light. An advantage of this is that the solid-state light source can be formed as a compact device. For example, the layer of phosphor having sufficient thickness can achieve complete conversion.

In a further embodiment the solid-state light source further comprises a control unit for independently controlling the intensity of at least one of the excitation light and the primary light.

In a further embodiment, the control unit comprises is a variable resistor.

The intensity of light emitted from the first active region and the second active region can be varied by separately regulating one or both of the voltages supplied to the first and second active regions. By independently controlling the active regions the respective intensity of a spectrum can be regulated, for example, to adjust the color temperature of the mixed light. Current control devices such as resistors or the likes, which have a variable resistance, are used in the control unit. By independently controlling the currents to the first and second active region, the white point of the solid-state light source may be suitably adjusted.

According to a further aspect of the invention a backlight unit comprises such a solid-state light source.

According to yet a further aspect of the invention a display module comprises such a backlight unit.

According to yet a further aspect of the invention a portable electronic device comprises such a display module.

According to a further aspect of the invention a lamp comprises one or more such solid-state light sources. Such a lamp is advantageously used in automobile lighting.

Several such solid-state light sources according to the invention can be included into a lamp, or into a backlight unit to provide illumination to a display of a portable electronic device such as a mobile phone, PDA etc.

According to a further aspect thereof, the present invention provides a method of producing light of a desired color point from a solid state light source, the method comprising the steps of: generating excitation light from the first active region and generating primary light from the second active region; next, substantially converting the excitation light into the secondary light by using a conversion element; next, mixing the primary light and the secondary light thereby producing light of a desired color point. The advantages have been described previously.

These and further aspects of the present invention will become apparent from and will be elucidated with respect to the embodiments described hereinafter with reference to the accompanying drawings. The drawings illustrate the embodiments of the invention, and together with the description, serve to further explain the principles of the invention. In the drawings:

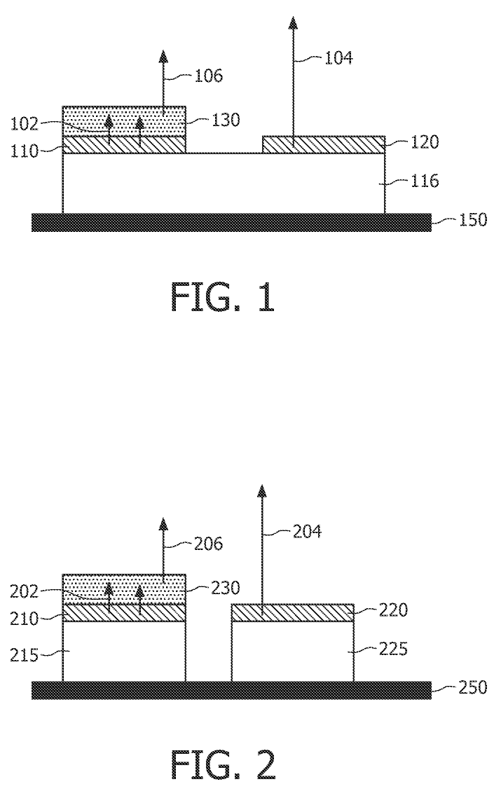

FIG. 1 is a schematic representation of a first embodiment of the invention showing the first active region and the second active region formed on a single substrate.

FIG. 2 shows a schematic representation of a second embodiment of the invention showing the first active region and the second active region formed on different substrates.

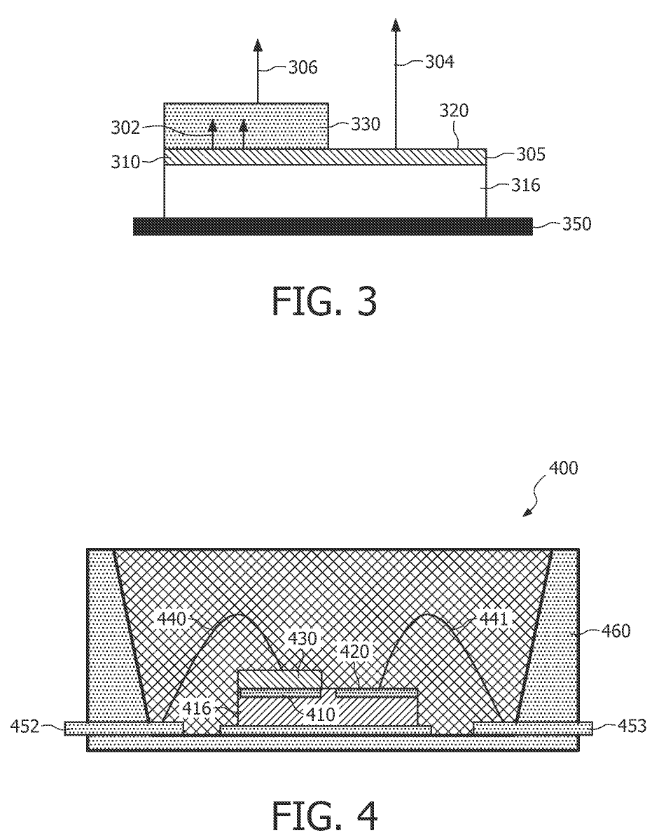

FIG. 3 shows a schematic representation of a third embodiment of the invention showing the first active region and the second active region formed as part of a single common active region.

FIG. 4 shows a schematic representation of a fourth embodiment of the invention showing a solid-state light source assembled into a single package.

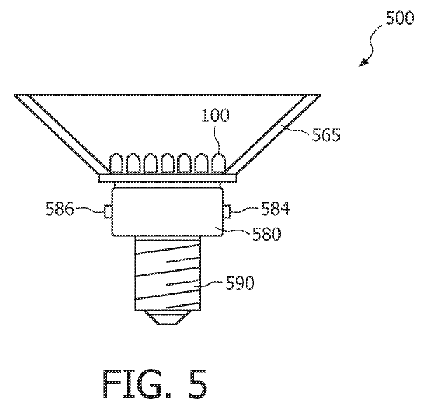

FIG. 5 shows a schematic representation of a lamp of the invention comprising several solid-state light sources.

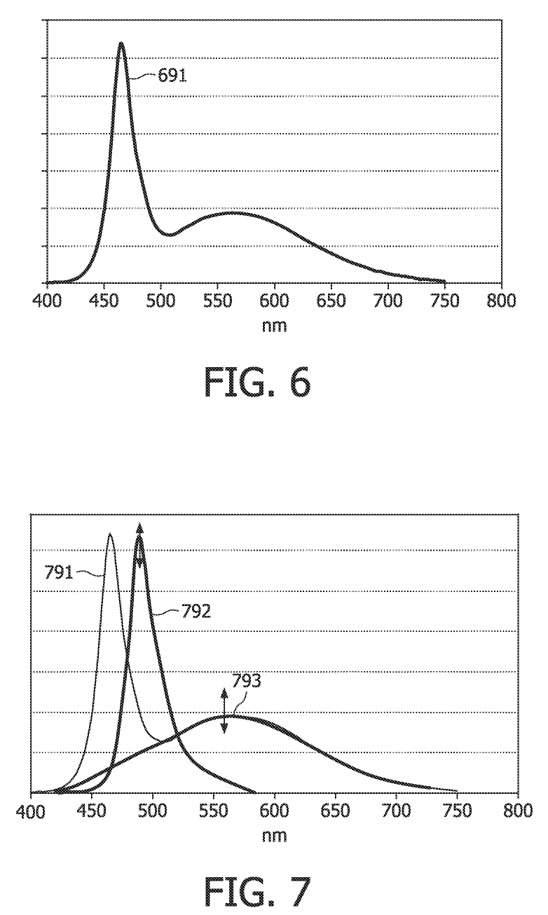

FIG. 6 shows a schematic representation of a spectrum of a typical white LED.

FIG. 7 shows a schematic representation of a combine spectrum of two active regions.

In the Figures, components with the same function are referenced by similar reference signs.

Generally, in portable electronic devices such as mobile phones, PDAs, etc., light from solid-state light sources, for example LEDs etc., which are assembled in a backlight unit, provides illumination to a liquid crystal display (LCD) panel. It is advantageous that such portable electronic devices have an adjustable color temperature and high contrast to improve readability and viewing on the LCD depending on the application.

FIG. 1 shows a simplified schematic representation of a first embodiment of the invention showing a first active region 110 and a second active region 120 formed on a single substrate 116. The active regions 110, 120 are formed adjacent to, but separated from each other. For example, semi-conducting materials such as GaN (gallium nitride), ZnSe, AlGaInN, InGaN, etc., can be used to form the active regions 110, 120. The substrate 116, for example a transparent sapphire acting as a common electrode, is mounted on a first connector 150, for example a leadframe forming the cathode connection. This leadframe is electrically connected to a control unit, which supplies the required power to driver the solid-state light source 100. The active regions 110, 120 may be formed by means of epitaxy or the like either on a single substrate 116 or as well on independent respective substrates. The first active region 110 and the second active region 120 preferably emit excitation light 102 and primary light 104 in the blue wavelength range of the visible spectrum when a forward bias is applied.

The first active region 110 is associated with a phosphor 130, for example a commonly used phosphor. In the figures, the phosphor 130 is always depicted in its preferred embodiment as a layer covering the first active region 110 for simplicity, however other arrangements may be envisaged. Preferably, the phosphor 130 is deposited on the first active region 110 as a relatively thick layer, thus being fully saturated. The phosphor 130 can as well be separated from the first active region 110, in which case an optical element is used to direct the excitation light 102 from the first active region 110 onto the phosphor 130.

The phosphor 130 is capable of substantially converting the excitation light 102 into secondary light 106. In a preferred embodiment, the phosphor may completely convert the excitation light 102 into the secondary light 106. The excitation light 102 and the primary light 104 are for example in color ranges belonging to the blue or red or green or violet or UV frequency ranges. The secondary light 106 is preferably in a color range that is complementary to the color of the primary light 104, and preferably in a broad spectral range around and including yellow. Complementary colors are contrasting and involves two colors approximately 180° apart in hue which stand out against each other. Complementary colors can be combined to yield white light.

In a preferred embodiment, the phosphor 130 completely converts blue excitation light 102, preferably blue light in the wavelength range of 450-495 nm, into secondary light 106, which is preferably light of a broad spectrum around and including yellow in the wavelength range of 500-622 nm, and more particularly in the range of 570-600 nm. The primary light 104 and the secondary light 106 are then mixed to produce mixed white light that has a desired and reproducible color temperature. The intensity of the excitation light 102 and primary light 104 can be a controlled to adjust the white point of the mixed light emitted by the solid-state light source 100.

FIG. 2 shows a schematic representation of a second embodiment of the invention showing the first active region 210 formed on a first substrate 215 and the second active region 220 formed on a second substrate 225. The first active region 210 is associated with the phosphor 230, wherein the phosphor completely converts the excitation light 202 emitted from the first active region 210 into the secondary light 206. The connector 250 is electrically connected to the substrates 215, 225, and also connected to a control unit that provides the required voltage to drive the solid-state light source. Other operational details are similar to those described previously in FIG. 1.

FIG. 3 shows a schematic representation of a third embodiment of the invention showing the first active region 310 and the second active region 320 formed as part of a single common active region 305 on a single substrate 316. A single common active region 305 is formed on a single substrate 316, for example forming the cathode connection, which is attached to a first connecting means 350. A first portion of the single common active region 305 is covered by an excess amount of phosphor 330. In a preferred embodiment, the first portion forms the first active region 310 and all excitation light 302 emitted by the first active region 310 is completely converted by the phosphor 330 into secondary light 306. A second portion of the single common active region 305 that is not covered by the phosphor 330 forms the second active region 320 and emits the primary light 304. Since, all excitation light 302 from the first active region 310 is converted into the secondary light 306, the secondary light 306 and the primary light 304 are mixed to produce white light that has a desired and reproducible color temperature. Other operational details are similar to those described previously in FIG. 1.

FIG. 4 shows a schematic representation of a packaged LED 400, including the first embodiment of the solid-state light source in accordance with the invention comprising a first active region 410 and a second active region 420. The package includes a reflective casing 460 to enhance the reflectivity by preventing the loss of light due to absorption. The first active region 410 is electrically connected to a second connector 452, preferably a leadframe via a bonding wire 440 and the second active region 420 is electrically connected to a third connector 453, also preferably a leadframe via a bonding wire 441. The first active region 410 and the second active region 420 form the anode connections. The anodes and the cathode are connected to a power control unit, such as an external driving circuitry not shown in the figure. When the solid-state light source is operated in forward bias mode, the active regions 410, 420 are supplied with the required voltage and emit light. Preferably, the voltages supplied to the first 400 and second 420 active regions can be independently controlled to obtain mixed white light of a desired color temperature. By regulating the current supplied to the first active region 410 and the second active region 420, the intensity or power of the emission spectrum can be easily regulated and the white point color temperature can be suitable adjusted. As a result, a light source with a variable color temperature may be realized using this simple structure. This is because the luminous intensity of the yellow emitting phosphor 430 is essentially correlated with that of the emission from the second active region 420 as its photo-excitation source. Thus, by appropriately controlling the luminous intensities of the first active region 410 and the second active region 420 the solid-state light source 400 can be made to produce light of any arbitrary color. Preferably, the connectors 450, 452, 453 and the wire bonds 440, 441 comprise the same metal such that they have the same electrical and thermal properties, leading to improved conductivity as compared to situations wherein different materials are used. Other operational details are similar to those described previously in FIG. 1.

FIG. 5, being reproduced from FIG. 21 of EP-1160883-A1, shows a lamp 500 in accordance with the invention comprising several LEDs 100. The lamp comprises a reflector 565, a power supply unit 580 for supplying power to the LEDs 100, and a base 590. In addition the lamp 500 has a color control dial 586 and a brightness control dial 584 which can be used to control the color and brightness of the lamp 500, which has been described in EP-1160883-A2.

FIG. 6 shows a schematic representation of a spectrum 691 of a typical white LED. For example, the spectrum 691 is typical that of a LED with a phosphor combined. The x-axis represents wavelength in nanometers (nm) and the y-axis represents intensity. White LEDs exhibits a first strong peak at about 450 nm, which is blue light, and a second flatter peak centered around 570-580 nm, which is yellow light. Mixing the blue light with the yellow light produces white light. Noticeably, the peak intensity of the blue emission is higher than that of any other emission. The higher the intensity of the blue emission, the higher is the correlated color temperature of the solid-state light source.

FIG. 7 shows a schematic representation of spectrum of a white LED according to a preferred embodiment of the invention. The x-axis represents wavelength in nanometers (nm) and the y-axis represents intensity. The first active region 110 emits a spectrum 791 in the blue wavelength range within the range of 450-490 nm. The spectrum 791 is completely converted by the phosphor 130 into another broader spectrum 792, which has a flatter peak centered around and including the yellow wavelength range of 500-580 nm. Preferably, since the blue light emitted from the first active region 110 is completely converted to yellow light, the second active region 120 is arranged to emit a spectrum 792 that adds to the blue spectrum.

As discussed previously, the current to the first active region 110 and second active region 120 can be independently controlled thereby independently regulating the intensities of the emission from these active regions. The double-headed arrows on the peak of the spectrum 792 of the blue light, and peak of the spectrum 393 of the yellow light indicate that controlling the current supplied to the first active region 110 and second active region 120 can regulate the intensities of the blue and yellow light. As a result of regulating the current supplied to each of the first active region 110 and second active region 120 by the control unit, the intensities are suitably adjusted, thereby adjusting the correlated color temperature of the white light produced, for example to obtain tropical daylight, neutral white, warm white or that of any incandescent lamp.

It should be noted that the above-mentioned embodiments illustrate rather than limit the invention and that those skilled in the art will be able to design alternative embodiments without departing from the scope of the appended claims. In the claims, any reference signs should not limit the scope of the claim. The invention may be accomplished by combining the various embodiments described above. The invention can be implemented by means of hardware comprising several distinct elements as well as by integrated solutions.

It should further be noted that use of the verb “comprises/comprising” and its conjugations in this specification, including the claims, is understood to specify the presence of stated features, integers, steps, components or groups thereof but not to exclude the presence of further features. It should also be noted that the indefinite article “a” or “an” preceding an element in a claim does not exclude the presence of a plurality of such elements. Furthermore, the invention resides in each and every novel feature or combination of features.

The invention may be summarized as follows: a solid-state light source comprising a first active region for emitting an excitation light and a second active region for emitting a primary light, and a conversion element for substantially converting the excitation light into a secondary light. The primary light and the secondary light are mixed to produce light of a desired color point, in particular white light with a predetermined color temperature.

1. A solid-state light source (100) comprising: a first active region (110) for emitting excitation light (102), a second active region (120) for emitting primary light (104), and a conversion element (130) for substantially converting the excitation light (102) into secondary light (106); and the solid-state light source (100) is further arranged to provide a mixing of the primary light (104) and the secondary light (106).

2. The solid-state light source (100) as claimed in claim 1, wherein the excitation light (102) and the primary light (104) are in the same wavelength range.

3. The solid-state light source (100) as claimed in claim 1, wherein the first active region (10) and the second active region (120) are formed on a single substrate (116).

4. The solid-state light source (100) as claimed in claim 3, wherein the first active region (110) and the second active region (120) are arranged within a single common active region (305).

5. The solid-state light source (100) as claimed in claim 1, wherein the first active region (110) is formed on a first substrate (115) and the second active region (120) is formed on a second substrate (125).

6. The solid-state light source (100) as claimed in claim 1, wherein the conversion element (130) comprises a layer essentially covering the first active region (110) only.

7. The solid-state light source (100) as claimed in claim 1, further comprising a control unit for independently controlling the intensity of at least one of the excitation light (102) and the primary light (104).

8. The solid-state light source (100) as claimed in claim 7, wherein the control unit comprises a variable resistor.

9. A backlight unit comprising a solid-state light source (100) as claimed in claim 1.

10. A display module comprising a backlight unit as claimed in claim 9.

11. A portable electronic device comprising a display module as claimed in claim 10.

12. A lamp (400) comprising one or more solid-state light sources (110) as claimed in claim 1.

13. A method of producing light of a desired color point from a solid-state light source (110), the method comprising the steps:
generating excitation (102) light from the first active region (110)
generating primary light (104) from the second active region (120)
substantially converting the excitation light (102) into secondary light (106) by using the conversion element (130);
mixing the primary light (104) and the secondary light (106) thereby producing light of the desired color point.
